(19) United States
(12) Patent Application Publication
(10) Pub. No.: US 2022/0158137 A1
(43) Pub. Date: May 19, 2022

(54) ORGANIC LIGHT-EMITTING DISPLAY SUBSTRATE, METHOD FOR MANUFACTURING SAME, DISPLAY PANEL, AND DISPLAY DEVICE

(71) Applicant: BOE Technology Group Co., Ltd., Beijing (CN)

(72) Inventor: Shantao CHEN, Beijing (CN)

(21) Appl. No.: 17/387,916

(22) Filed: Jul. 28, 2021

(30) Foreign Application Priority Data
Nov. 19, 2020 (CN) 202011303534.3

(51) Int. Cl. H01L 51/52; H01L 51/56

(52) U.S. Cl. CPC H01L 51/5281; H01L 51/56; H01L 27/3246; H01L 51/525; H01L 2227/323

(57) ABSTRACT

An organic light-emitting display substrate is provided. The organic light-emitting display substrate includes: a first display region and a second display region, wherein the first display region is a photographing region, and the second display region is a conventional display region. The organic light-emitting display substrate includes: a base and a pixel defining layer that are laminated and a plurality of microlens arrays that are distributed at intervals on the pixel defining layer, wherein the plurality of microlens arrays are disposed in the first display region, the pixel defining layer is provided with a plurality of openings penetrating the pixel defining layer, and orthographic projections of the plurality of microlens arrays on the base and orthographic projections of the openings on the base do not overlap.

### CROSS-REFERENCE TO RELATED APPLICATION

This application claims priority to Chinese Patent Application No. 202011303534.3, filed on Nov. 19, 2020 and entitled “ORGANIC LIGHT-EMITTING DISPLAY SUBSTRATE, METHOD FOR MANUFACTURING SAME, DISPLAY PANEL, AND DISPLAY DEVICE”, the disclosure of which is incorporated herein by reference in its entirety.

### TECHNICAL FIELD

The present disclosure relates to the field of display technologies, and in particular, relates to an organic light-emitting display substrate, a method for manufacturing the same, a display panel, and a display device.

### BACKGROUND

A full screen has a relatively high screen-to-body ratio, and is increasingly widely applied in the field of display technologies, for example, full-screen display phones. A full-screen phone includes an organic light-emitting diode (OLED) display panel and a camera. The camera is usually disposed on the back side of the display panel, to implement the design of an under-screen camera, thereby increasing the screen-to-body ratio of the mobile phone.

### SUMMARY

The present disclosure provides an organic light-emitting display substrate, a method for manufacturing the same, a display panel, and a display device.

In a first aspect, the embodiments of the present disclosure provide an organic light-emitting display substrate. The organic light-emitting display substrate is provided with a first display region and a second display region, wherein the first display region is a photographing region, and the second display region is a conventional display region. The organic light-emitting display substrate includes: a base and a pixel defining layer that are laminated and a plurality of microlens arrays that are distributed at intervals on the pixel defining layer. The plurality of microlens arrays are disposed in the first display region. The pixel defining layer is provided with a plurality of openings penetrating the pixel defining layer. Orthographic projections of the plurality of microlens arrays on the base and orthographic projections of the openings on the base do not overlap.

In some embodiments, each of the plurality of microlens arrays includes a plate and a plurality of spherical caps that are arranged in an array on the plate, and the plate is disposed between bottom surfaces of the spherical caps and the pixel defining layer.

In some embodiments, a thickness of each of the microlens arrays ranges from 1 μm to 2 μm.

In some embodiments, a diameter of each of the spherical caps ranges from 2 μm to 10 μm.

In some embodiments, a distance between two adjacent spherical caps is 0.

In some embodiments, the organic light-emitting display substrate further includes a first electrode layer, wherein the pixel defining layer is disposed between the first electrode layer and the plurality of microlens arrays; and the first electrode layer includes a plurality of first electrodes, and the orthographic projections of the openings on the base are within orthographic projections of the first electrodes on the base.

In some embodiments, the organic light-emitting display substrate further includes a plurality of spacers, wherein the pixel defining layer is disposed between the first electrode layer and the plurality of spacers; and the plurality of spacers are disposed in the second display region, and orthographic projections of the plurality of spacers on the base and the orthographic projections of the openings on the base do not overlap.

In some embodiments, a material of the plurality of spacers is the same as a material of the plurality of microlens arrays.

In some embodiments, a material of the plurality of microlens arrays is the same as a material of the pixel defining layer.

In some embodiments, the organic light-emitting display substrate further includes: an organic light-emitting layer, wherein the organic light-emitting layer is disposed in the opening and electrically connected with the first electrode layer; and a second electrode layer, wherein the organic light-emitting layer is disposed between the second electrode layer and the first electrode layer, and the second electrode layer is electrically connected with the organic light-emitting layer.

In some embodiments, a material of the plurality of microlens arrays is photoresist.

In a second aspect, the embodiments of the present disclosure provide a display panel. The display panel includes the organic light-emitting display substrate in the first aspect.

In a third aspect, the embodiments of the present disclosure provide a display device. The display device includes the display panel in the second aspect.

In a fourth aspect, the embodiments of the present disclosure provide a method for manufacturing an organic light-emitting display substrate. The organic light-emitting display substrate includes a first display region and a second display region. The first display region is a photographing region, and the second display region is a conventional display region. The method for manufacturing an organic light-emitting display substrate includes: providing a base; and sequentially forming, on the base, a pixel defining layer and a plurality of microlens arrays that are arranged at intervals, wherein the plurality of microlens arrays are disposed in the first display region, the pixel defining layer is provided with a plurality of openings penetrating the pixel defining layer, and orthographic projections of the plurality of microlens arrays on the base and orthographic projections of the openings on the base do not overlap.

In some embodiments, the method further includes: forming a first electrode layer on a side of the base, wherein the first electrode layer includes a plurality of first electrodes; and sequentially forming, on the base, the pixel defining layer and the plurality of microlens arrays that are arranged at intervals includes: forming the pixel defining layer on a side, away from the base, of the first electrode layer, and patterning the pixel defining layer to form the plurality of openings penetrating the pixel defining layer, wherein the orthographic projections of the openings on the base are within an orthographic projection of one first electrode on the base; and forming a light transmitting material layer on a side, away from the base, of the pixel defining layer, and patterning the light transmitting material layer to form the plurality of microlens arrays, wherein the plurality of microlens arrays are disposed in the first display region, and the orthographic projections of the plurality of microlens arrays on the base and the orthographic projections of the openings on the base do not overlap.

In some embodiments, the method further includes: forming a plurality of spacers at the same time of patterning the light transmitting material layer to form the plurality of microlens arrays, wherein the plurality of spacers are disposed in the second display region, and orthographic projections of the plurality of spacers on the base and the orthographic projections of the openings on the base do not overlap.

In some embodiments, forming the plurality of spacers at the same time of patterning the light transmitting material layer to form the plurality of microlens arrays includes: exposing the light transmitting material layer by using a halftone mask, wherein the halftone mask includes a first exposure region corresponding to the plurality of microlens arrays and a second exposure region corresponding to the plurality of spacers. The first exposure region is a halftone region, and the second exposure region is a fully light transmitting region.

In some embodiments, forming the plurality of spacers at the same time of patterning the light transmitting material layer to form the plurality of microlens arrays further includes: developing the exposed light transmitting material layer, to obtain the plurality of microlens arrays to be cured and the plurality of spacers to be cured; and performing curing on the developed light transmitting material layer to form the plurality of microlens arrays and the plurality of spacers, including: performing primary curing, at a first temperature, on the developed light transmitting material layer, and performing secondary curing, at a second temperature, on the light transmitting material layer after the primary curing, wherein the first temperature is different from the second temperature.

### BRIEF DESCRIPTION OF THE DRAWINGS

FIG. 1 is a schematic top view of a structure of an organic light-emitting display substrate according to an embodiment of the present disclosure;

FIG. 2 is a schematic top view of a structure of a first display region of an organic light-emitting display substrate according to an embodiment of the present disclosure;

FIG. 3 is a schematic sectional view of the organic light-emitting display substrate shown in FIG. 2 in an A-A direction;

FIG. 4 is a schematic diagram of refraction of a pixel defining layer in an organic light-emitting display substrate in the related art;

FIG. 5 is a schematic diagram of refraction of a pixel defining layer in an organic light-emitting display substrate according to an embodiment of the present disclosure;

FIG. 6 is a schematic top view of a structure of a second display region of an organic light-emitting display substrate according to an embodiment of the present disclosure;

FIG. 7 is a schematic sectional view of the organic light-emitting display substrate shown in FIG. 6 in a B-B direction;

FIG. 8 is a schematic sectional view of a first display region of an organic light-emitting display substrate according to an embodiment of the present disclosure;

FIG. 9 is a schematic sectional view of a display panel according to an embodiment of the present disclosure;

FIG. 10 is a schematic structural diagram of a display device according to an embodiment of the present disclosure;

FIG. 11 is a flowchart of a method for manufacturing an organic light-emitting display substrate according to an embodiment of the present disclosure;

FIG. 12 is a flowchart of a method for manufacturing an organic light-emitting display substrate according to an embodiment of the present disclosure; and

FIG. 13 is a flowchart of step S4 in the method for manufacturing an organic light-emitting display substrate shown in FIG. 12.

### REFERENCE NUMERALS

1—organic light-emitting display substrate; 2—camera;
M1—first display region; M2—second display region;
101—base; 102—buffer layer; 103—active layer; 1031—active island; 104—first insulating layer; 105—gate layer; 1051—gate; 106—second insulating layer; 107—source/drain electrode layer; 1071—source; 1072—drain; 108—third insulating layer; 109—planarization layer; 110—first electrode layer; 1101—first electrode; 111—pixel defining layer; 1111—opening; 112—microlens array; 1121—spherical cap; 1122—plate; 112′—spacer; 113—organic light-emitting layer; 114—second electrode layer; and 115—encapsulation layer.

### DETAILED DESCRIPTION

The present disclosure is described below in detail. Examples of the embodiments of the present disclosure are shown in the accompanying drawings. The same or similar reference numerals indicate the same or similar parts or parts having the same or similar functions throughout the present disclosure. In addition, if the detailed descriptions of the prior art is not necessary for the features shown in the present disclosure, the detailed descriptions are omitted. The following embodiments illustrated with reference to the accompanying drawings are exemplary, and are only intended to explain the present disclosure but cannot be construed as a limitation to the present disclosure.

It can be understood by persons skilled in the art that all terms (including technical terms and scientific terms) used herein have the same meanings as those generally understood by persons of ordinary skill in the art of the present disclosure, unless otherwise defined. It should be further understood that terms such as those defined in general dictionaries should be understood to have the same meanings as those in the context of the related art, and shall not be understood to have ideal or too formal meanings unless particularly defined herein.

Persons skilled in the art can understand that the singular forms “a,” “an,” and “the” used herein are intended to include the plural forms as well, unless specifically stated. It should be further understood that the term “include/comprise” used in the description of the present disclosure indicates the presence of a feature, an integer, a step, an operation, an element and/or a component, but does not exclude the presence or addition of one or more other features, integers, steps, operations, elements, components and/or combinations thereof.

In the related art, a camera is usually disposed at the back side of a display panel, to implement the design of an under-screen camera. In such a design, incident light needs to pass through a display substrate to be acquired by the camera. However, the light transmittance of the display substrate in the related art is relatively low, such that the photographing effect of the under-screen camera is relatively poor. Although the light transmittance of the display substrate can be increased to some extent by changing the materials of the film layers, the effect cannot necessarily meet the expectations. In addition, because of the change in materials, wiring and pixel arrangement in the display substrates needs to be adaptively adjusted, which is difficult in design and subsequent testing, and brings high costs.

To solve the foregoing technical problems in the related art, the present disclosure provides an organic light-emitting display substrate, a method for manufacturing the same, a display panel, and a display device.

The technical solutions of the present disclosure and how the technical solutions of the present disclosure solve the foregoing technical problems are described in following the optional embodiments.

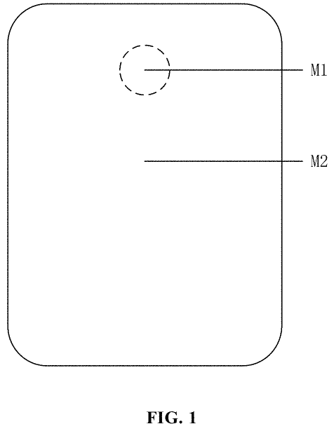

FIG. 1 is a schematic top view of a structure of an organic light-emitting display substrate according to an embodiment of the present disclosure. Referring to FIG. 1, the organic light-emitting display substrate includes a first display region M1 and a second display region M2. The first display region M1 is a photographing region, and the second display region M2 is a conventional display region.

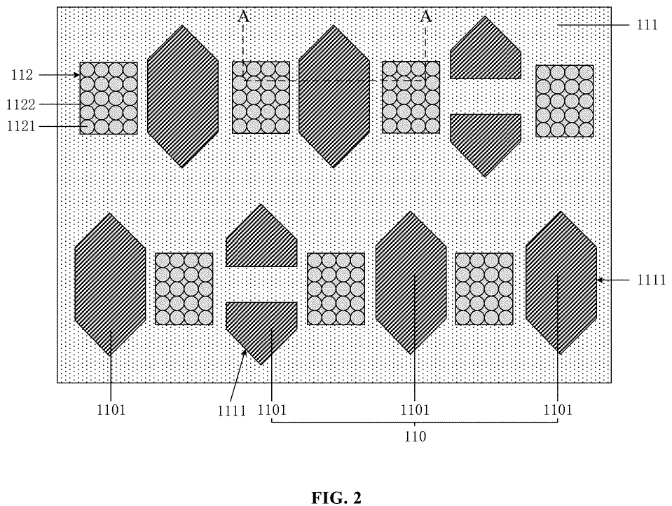

FIG. 2 is a schematic top view of a structure of a first display region of an organic light-emitting display substrate according to an embodiment of the present disclosure. Referring to FIG. 2, the organic light-emitting display substrate includes a plurality of microlens arrays 112 that are arranged at intervals. The plurality of microlens arrays 112 are disposed in the first display region M1.

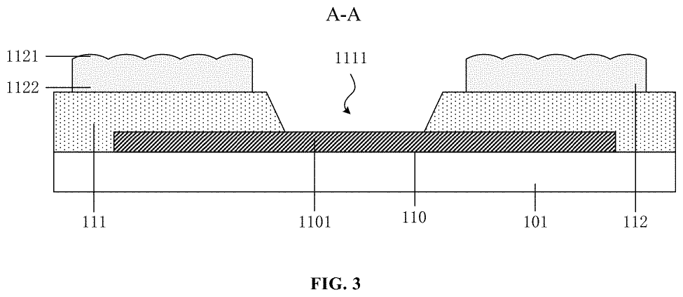

FIG. 3 is a schematic sectional view of the organic light-emitting display substrate shown in FIG. 2 in an A-A direction. Referring to FIG. 3, the organic light-emitting display substrate further includes a base 101 and a pixel defining layer 111 that are laminated in sequence. The plurality of microlens arrays 112 are disposed on the pixel defining layer 111. The pixel defining layer 111 is provided with a plurality of openings 1111 penetrating the pixel defining layer 111. The orthographic projections of the plurality of microlens arrays 112 on the base 101 and the orthographic projections of the openings 1111 on the base 101 do not overlap. The openings 1111 corresponding to different pixels have different shapes and sizes. For example, as shown in FIG. 2, the openings 1111 corresponding to red pixels and green pixels are hexagons, and the openings 1111 corresponding to blue pixels are pentagons.

In the embodiment of the present disclosure, a plurality of microlens arrays 112 are arranged in the first display region M1, that is, the photographing region. The plurality of microlens arrays 112 may increase the light transmittance of the first display region M1, such that the camera disposed below the first display region M1 can acquire more incident light, to improve the photographing effect.

Referring to FIG. 3 again, the organic light-emitting display substrate further includes a first electrode layer 11. The pixel defining layer 111 is disposed between the first electrode layer 110 and the plurality of microlens arrays 112. The first electrode layer 110 includes a plurality of first electrodes 1101. The orthographic projection of each opening 1111 on the base 101 is within the orthographic projection of one first electrode 1101 on the base 101.

In the organic light-emitting display substrate provided in the embodiment of the present disclosure, the microlens arrays 112 are disposed on the pixel defining layer 111. As the microlens arrays 112 can reduce the reflection of incident light, the light transmittance of the region, provided with the microlens arrays 112, of the organic light-emitting display substrate can be increased, such that the camera disposed below the region can acquire more incident light, thereby improving the photographing effect.

In some embodiments, as shown in FIG. 2 and FIG. 3, each of microlens arrays 112 includes a plate 1122 and a plurality of spherical caps 1121 that are arranged in an array on the plate 1122. Bottom surfaces of the spherical caps 1121 are attached to one surface of the plate 1122.

The surface of the spherical cap 1121 is an arc-shaped surface. The arc-shaped surface has the convergence function of enabling more light to pass through the microlens arrays 112, thereby increasing the light transmittance of the first display region M1.

For example, the plate 1122 includes two opposite surfaces and a side face connecting the two surfaces. One of the two surfaces faces the first electrode layer 110, and the other one of the two surfaces faces the bottom surfaces of the spherical caps 1121.

In some embodiments, the distance between adjacent spherical caps 1121 is 0, such that the microlens arrays 112 can better improve the light transmission effect.

In some embodiments, the diameter of the spherical cap 1121 ranges from 2 μm to 10 μm, and the thickness of the microlens array 112 ranges from 1 μm to 2 μm. For example, the diameter of the spherical cap 1121 is 5 μm, and the thickness of the microlens array 112 is 1.5 μm.

In some embodiments, in the organic light-emitting display substrate provided in the embodiment of the present disclosure, the material of the microlens arrays 112 is the same as the material of the pixel defining layer 111.

In some embodiments, in the organic light-emitting display substrate provided in the embodiment of the present disclosure, the material of the microlens arrays 112 is photoresist. For example, the material of the microlens arrays 112 is photosensitive polyimide. Photosensitive polyimide can not only be used to form the microlens arrays 112 but also be used to form spacers 112′. Photosensitive polyimide has a relatively high light transmittance and may be patterned by light illumination. In addition, photosensitive polyimide has high thermal stability, high insulation, low dielectric constant, and relatively high mechanical strength.

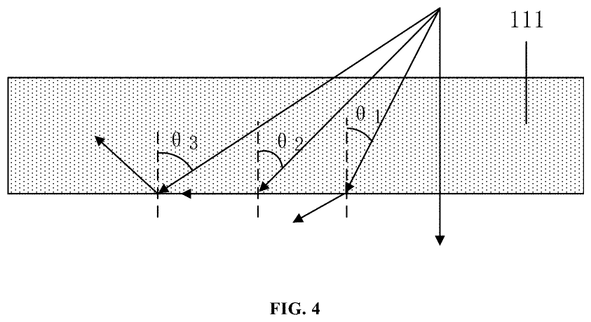

FIG. 4 is a schematic diagram of refraction of a pixel defining layer in an organic light-emitting display substrate in the related art. As shown in FIG. 4, in the organic light-emitting display substrate that is not provided with the microlens arrays 112, when the incident angle of light incident into the pixel defining layer 111 is relatively small (for example, the first incident angle θ1), light can be reflected from the pixel defining layer 111. Once the incident angle is greater than a critical angle θ2 (for example, the second incident angle θ3) of refraction, light cannot be reflected from the pixel defining layer 111.

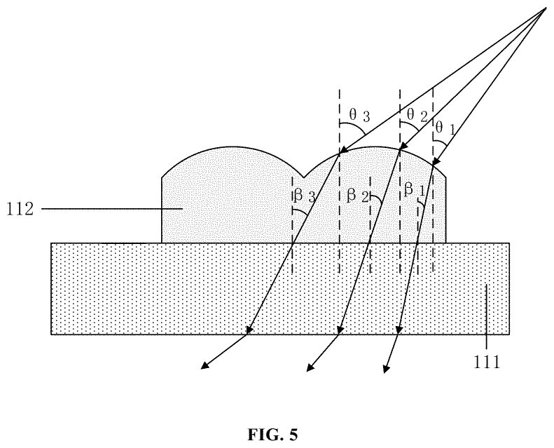

FIG. 5 is a schematic diagram of refraction of a pixel defining layer in an organic light-emitting display substrate according to an embodiment of the present disclosure. Referring to FIG. 4 and FIG. 5, it should be noted that structures of the film layers on the pixel defining layer 111 in the related art are basically the same as those of the film layers on the microlens arrays in the present disclosure. In this case, under the condition of the same external light, incident light projected to the pixel defining layer 111 in FIG. 4 is basically the same as the incident light projected on microlenses in FIG. 5.

As shown in FIG. 5, in the organic light-emitting display substrate provided with the microlens arrays 112, as the arc-shaped surface of the microlens array 112 has the convergence function, after light is incident into the microlens arrays 112 at angles θ1, θ2 and θ3 respectively, the incident light, after passing through the microlenses, is incident into the pixel defining layer 111 at angles β1 (β1<θ1), β2 (β2<θ2), and β3 (β3<θ3) respectively, such that light that originally cannot pass through the pixel defining layer 111 can pass through the pixel defining layer 111, to enter the film layers. Therefore, the transmittance of the display substrate is improved. Through verification, after the microlens arrays 112 are disposed, light transmittance in the first display region M1 of the display substrate is increased by two to three times.

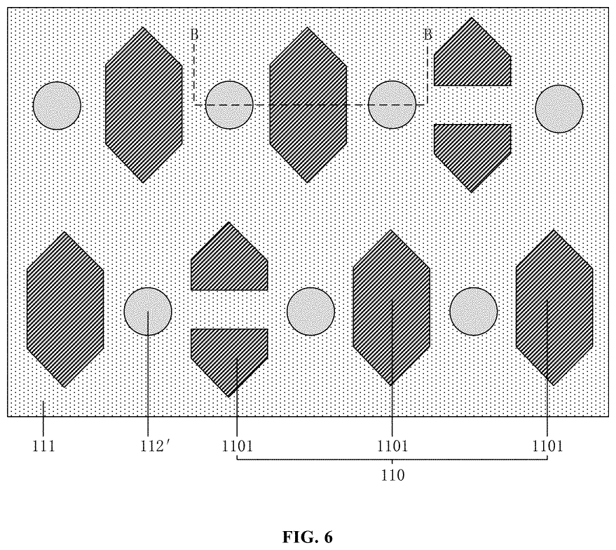

FIG. 6 is a schematic top view of a structure of a second display region of an organic light-emitting display substrate according to an embodiment of the present disclosure. As shown in FIG. 6, the organic light-emitting display substrate further includes a plurality of spacers 112′.

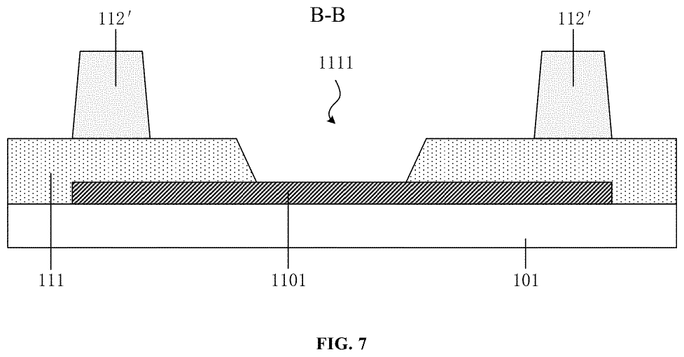

FIG. 7 is a schematic sectional view of the organic light-emitting display substrate shown in FIG. 6 in a B-B direction. Referring to FIG. 7, the pixel defining layer 111 is disposed between the spacers 112′ and the first electrode layer 110, and the spacers 112′ are disposed in the second display region M2. The orthographic projections of the spacers 112′ on the base 101 and the orthographic projections of the openings 1111 on the base 101 do not overlap.

In some embodiments, the material of the spacers 112′ is the same as the material of the microlens arrays 112.

The material of the spacers 112′ is the same as the material of the microlens arrays 112. That is, the microlens arrays 112 and the spacers 112′ may be formed at the same time. The microlens arrays 112 in the photographing region may be reused as the spacers 112′. That is, the microlens arrays 112 in the photographing region further plays the function of the spacers 112′, without providing the spacers 112′ additionally in the photographing region. Therefore, the manufacture of the microlens arrays 112 can be completed without additional procedures. That is, the light transmittance of the organic light-emitting display substrate can be improved without increasing production costs.

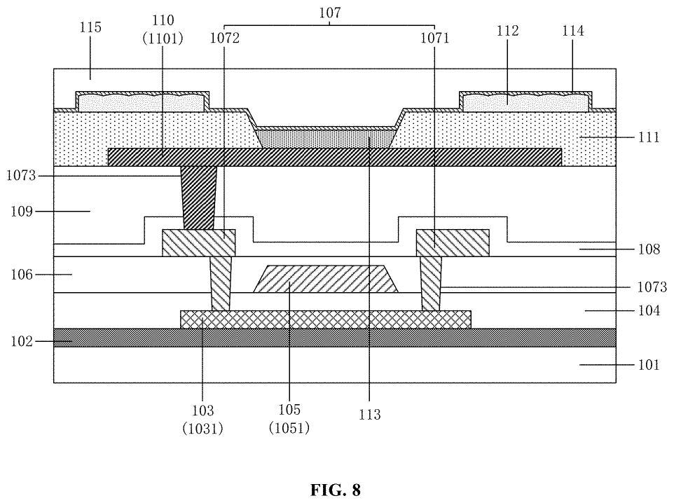

FIG. 8 is a schematic sectional view of a first display region of an organic light-emitting display substrate according to an embodiment of the present disclosure. As shown in FIG. 8, the organic light-emitting display substrate provided in the embodiments of the present disclosure further includes a buffer layer 102, a thin-film transistor layer, a planarization layer 109, an organic light-emitting layer 113, and a second electrode layer 114.

As shown in FIG. 8, the buffer layer 102 is disposed between the base 101 and the first electrode layer 110, and is configured to increase the bonding force between the base 101 and the thin-film transistor layer. The thin-film transistor layer is disposed between the buffer layer 102 and the first electrode layer 110, and is configured to form a driving circuit. The planarization layer 109 is disposed between the thin-film transistor layer and the first electrode layer 110. The organic light-emitting layer 113 is disposed in the opening 1111 and is disposed on the side, away from the base 101, of the first electrode layer 110. The second electrode layer 114 is disposed on the side, away from the base 101, of the microlens arrays 112.

In some embodiments, as shown in FIG. 8, the first electrode layer 110 is an anode layer, and the second electrode layer 114 is a cathode layer. For example, the first electrode layer 110 is an indium tin oxide (ITO) layer, and the second electrode layer 114 is a silver (Ag) layer.

In some embodiments, as shown in FIG. 8, the thin-film transistor layer includes an active layer 103, a first insulating layer 104, a gate layer 105, a second insulating layer 106, a source/drain electrode layer 107, and a third insulating layer 108 that are sequentially arranged in the direction from the base 101 to the pixel defining layer 111.

As shown in FIG. 8, the active layer 103 includes a plurality of active islands 1031. Each active island 1031 includes: a source region, a drain region, and a channel region between the source region and the drain region.

As shown in FIG. 8, the gate layer 105 includes a gate 1051 and a gate line (not shown in FIG. 8) that is electrically connected with the gate 1051. The orthographic projection of each gate 1051 on the base 101 is within the orthographic projection of the corresponding active island 1031 on the base 101.

As shown in FIG. 8, The source/drain electrode layer 107 includes a plurality of sources 1071, a plurality of drains 1072, and a plurality of data lines (not shown in FIG. 8). Each data line is electrically connected with the plurality of sources 1071, each source 1071 is electrically connected with the source region of the corresponding active island 1031 by a via 1073, and each drain 1072 is electrically connected with the drain region of the active island 1031 by a via 1073. The drain 1072 is further electrically connected with a corresponding first electrode 1101 by a via 1073.

As shown in FIG. 8, optionally, the display substrate further includes an encapsulation layer 115. The encapsulation layer 115 is disposed on the side, away from the base 101, of the second electrode layer 114. The encapsulation layer 115 can prevent water and oxygen from entering the organic light-emitting display substrate. In some embodiments, when the display substrate is a flexible substrate, the encapsulation layer 115 may be a thin-film encapsulation layer 115. When the display substrate is a rigid substrate, the encapsulation layer 115 may be a glass encapsulation layer 115.

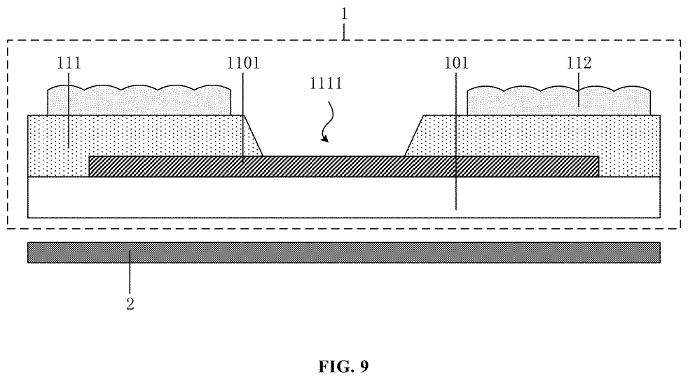

An embodiment of the present disclosure further provides a display panel. FIG. 9 is a schematic sectional view of a display panel according to an embodiment of the present disclosure. As shown in FIG. 9, the display panel provided in the embodiment of the present disclosure includes the organic light-emitting display substrate 1 in the foregoing embodiment, and has the beneficial effects of the organic light-emitting display substrate 1 in the foregoing embodiment. Details are not described again herein.

Furthermore, referring to FIG. 1 and FIG. 9, the display panel provided in the embodiment of the present disclosure includes a camera 2 disposed on the side, away from the first electrode 1101, of the base 101. The orthographic projection of the camera 2 on the base 101 is within the first display region M1.

The microlens arrays 112 are disposed on the pixel defining layer 111 in the first display region M1, such that the light transmittance of the first display region M1 can be increased, to increase the amount of incident light acquired by the camera 2, thereby increasing the photographing quality.

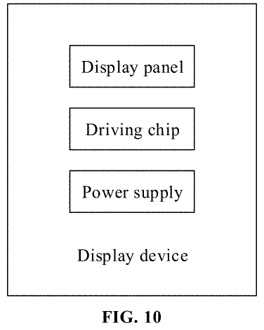

An embodiment of the present disclosure provides a display device. FIG. 10 is a schematic structural diagram of a display device according to an embodiment of the present disclosure. As shown in FIG. 10, the display device provided in the embodiment of the present disclosure includes the display panel in the foregoing embodiment and has the beneficial effects of the display panel in the foregoing embodiment. Details are not described again herein.

In some embodiments, the display device provided in the embodiment of the present disclosure further includes a driving chip and a power supply. The driving chip provides driving signals to the display panel. The power supply provides electrical energy to the display panel.

In some embodiments, the display device provided in the embodiment of the present disclosure may be a display device which needs an under-screen camera, such as a mobile phone or a tablet computer.

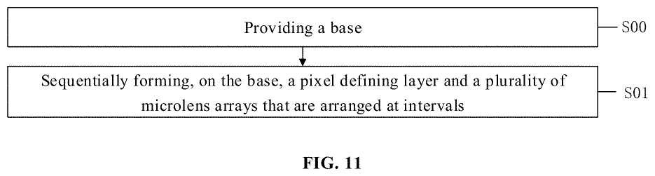

An embodiment of the present disclosure provides a method for manufacturing an organic light-emitting display substrate. The organic light-emitting display substrate includes a plurality of first display regions and a second display region. The first display region is a photographing region, and the second display region is a conventional display region. FIG. 11 is a flowchart of a method for manufacturing an organic light-emitting display substrate according to an embodiment of the present disclosure. Referring to FIG. 11. The method for manufacturing an organic light-emitting display substrate provided in the embodiment of the present disclosure includes the following steps.

In step S00, a base is provided.

In step S01, a pixel defining layer and a plurality of microlens arrays that are arranged at intervals are sequentially formed on the base.

The plurality of microlens arrays are disposed in the first display region. The pixel defining layer is provided with a plurality of openings penetrating the pixel defining layer. The orthographic projections of the plurality of microlens arrays on the base and the orthographic projections of the openings on the base do not overlap.

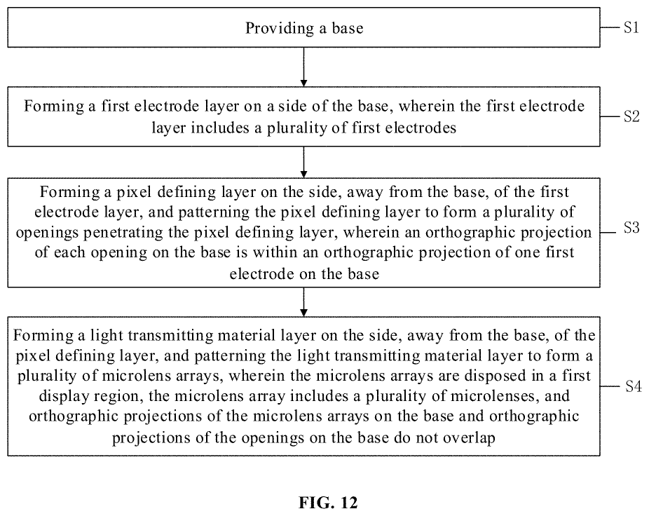

FIG. 12 is a flowchart of a method for manufacturing an organic light-emitting display substrate according to an embodiment of the present disclosure. Referring to FIG. 12, the method further includes the following steps.

In step S1, a base is provided.

In step S2, a first electrode layer is formed on a side of the base, wherein the first electrode layer includes a plurality of first electrodes.

In step S3, a pixel defining layer is formed on the side, away from the base, of the first electrode layer, and the pixel defining layer is patterned to form a plurality of openings penetrating the pixel defining layer, wherein the orthographic projection of each opening on the base is within the orthographic projection of one first electrode on the base.

In step S4, a light transmitting material layer is formed on the side, away from the base, of the pixel defining layer, and the light transmitting material layer is patterned to form a plurality of microlens arrays, wherein the microlens arrays are disposed in a first display region, the microlens array includes a plurality of microlenses, and the orthographic projections of the microlens arrays on the base and the orthographic projections of the openings on the base do not overlap.

In the method for manufacturing an organic light-emitting display substrate provided in the embodiment of the present disclosure, step S4 further includes: further forming a plurality of spacers at the same time of patterning the light transmitting material layer to form the plurality of microlens arrays, wherein the spacers are disposed in a second display region, and the orthographic projections of the spacers on the base and the orthographic projections of the openings on the base do not overlap. Patterning the light transmitting material layer includes performing exposure on the light transmitting material layer.

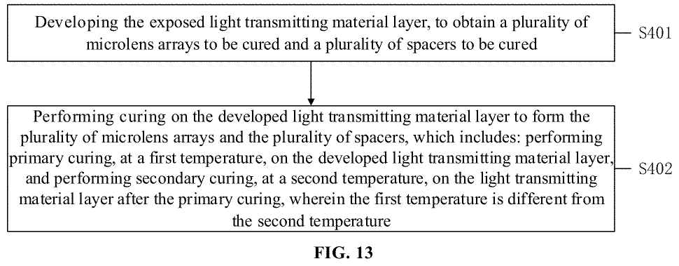

In some embodiments, FIG. 13 is a flowchart of step S4 in the method for manufacturing an organic light-emitting display substrate shown in FIG. 12. Referring to FIG. 13, in the method for manufacturing an organic light-emitting display substrate provided in the embodiment of the present disclosure, step S4 includes the following steps.

In S401, the exposed light transmitting material layer is developed, to obtain the plurality of microlens arrays to be cured and the plurality of spacers to be cured.

In S402, curing is performed on the developed light transmitting material layer to form the plurality of microlens arrays and the plurality of spacers, which includes: performing primary curing, at a first temperature, on the developed light transmitting material layer, and performing secondary curing, at a second temperature, on the light transmitting material layer after the primary curing, wherein the first temperature is different from the second temperature.

With the method of stepwise curing, the curing temperature in each step of curing can be controlled, so as to control the shape of the microlenses, to acquire the microlenses with a better morphology.

It may be understood by persons skilled in the art that the steps, measures and solutions in the operations, methods, and procedures discussed in the present disclosure may be alternated, changed, combined or deleted. Further, other steps, measures and solutions in the operations, methods, and procedures discussed in the present disclosure may also be alternated, changed, rearranged, decomposed, combined or deleted. Further, operations, methods, steps in flows, measures, and solutions in the related art and the present disclosure may also be alternated, changed, rearranged, decomposed, combined or deleted.

In the descriptions of the present disclosure, it should be understood that the orientation or positional relationship indicated by terms “center,” “up,” “down,” “front,” “rear,” “left,” “right,” “vertical,” “horizontal,” “top,” “bottom,” “in,” and “outside” are based on orientation or positional relationship shown in the accompanying drawings, and are intended only to facilitate descriptions of the present disclosure and simplify descriptions, but are not to indicate or imply that the devices or elements must be in the specific orientations or be constructed and operated in specific orientations, and therefore, cannot be construed as a limitation to the present disclosure.

The terms “first” and “second” are used only for descriptions, but are not to be understood as indicating or implying relative importance or implicitly specify the quantity of indicated technical features. Therefore, features defined by “first” and “second” may explicitly or implicitly include one or more features. In the descriptions of the present disclosure, the term “a plurality of” herein means “two or more”, unless otherwise specified.

In the descriptions of the present disclosure, it should be noted that unless otherwise expressly specified and defined, the terms “mounted,” “connected with,” and “connected to” should be understood in a broad sense. For example, the connection may be fixed connection, detachable connection, or integral connection, and may also be direct connection or connection through an intermediate medium, and may also be connection between two elements internally. For persons with ordinary skill in the art, the meanings of the above terms in the present disclosure should be understood according to specific conditions.

In the descriptions of the specification, specific features, structures, materials or characteristics may be combined as appropriate in any one or more embodiments or examples.

It should be understood that although the steps in the flowchart of the accompanying drawings are sequentially displayed as indicated by the arrows, these steps are not necessarily performed in the order indicated by the arrows. Unless explicitly stated herein, the execution of these steps is not strictly limited, and the steps may be executed in other orders. Moreover, at least some of the steps in the flowchart of the accompanying drawings may include a plurality of substeps or stages, which are not necessarily executed at the same time, but may be executed at different time. The sub-steps or stages are also not necessarily executed sequentially, but may be executed in turn or alternately with other steps or at least some of the sub-steps or stages in other steps.

Described above are merely some embodiments of the present disclosure. It should be noted that for persons with ordinary skill in the art, several improvements and modifications may further be made without departing from the principle of the present disclosure, and these improvements and modifications should also be included in the scope of protection of the present disclosure.

What is claimed is:

1. An organic light-emitting display substrate, wherein the organic light-emitting display substrate is provided with a first display region and a second display region, the first display region being a photographing region, and the second display region being a conventional display region; the organic light-emitting display substrate comprising: a base and a pixel defining layer that are laminated, and a plurality of microlens arrays that are distributed at intervals on the pixel defining layer, wherein the plurality of microlens arrays are disposed in the first display region, the pixel defining layer is provided with a plurality of openings penetrating the pixel defining layer, and orthographic projections of the plurality of microlens arrays on the base and orthographic projections of the openings on the base do not overlap.

2. The organic light-emitting display substrate according to claim 1, wherein each of the plurality of microlens arrays comprises a plate and a plurality of spherical caps that are arranged in an array on the plate, the plate being disposed between bottom surfaces of the spherical caps and the pixel defining layer.

3. The organic light-emitting display substrate according to claim 2, wherein a thicknesses of each of the microlens arrays ranges from 1 μm to 2 μm.

4. The organic light-emitting display substrate according to claim 2, wherein a diameter of each of the spherical caps ranges from 2 μm to 10 μm.

5. The organic light-emitting display substrate according to claim 2, wherein a distance between adjacent two of the plurality of spherical caps is 0.

6. The organic light-emitting display substrate according to claim 1, further comprising a first electrode layer, wherein
the pixel defining layer is disposed between the first electrode layer and the plurality of microlens arrays; and
the first electrode layer comprises a plurality of first electrodes, and the orthographic projections of the openings on the base are within orthographic projections of the first electrodes on the base.

7. The organic light-emitting display substrate according to claim 6, further comprising: a plurality of spacers, wherein
the pixel defining layer is disposed between the first electrode layer and the plurality of spacers; and
the plurality of spacers are disposed in the second display region, and orthographic projections of the plurality of spacers on the base and the orthographic projections of the openings on the base do not overlap.

8. The organic light-emitting display substrate according to claim 7, wherein a material of the plurality of spacers is the same as a material of the plurality of microlens arrays.

9. The organic light-emitting display substrate according to claim 6, wherein a material of the plurality of microlens arrays is the same as a material of the pixel defining layer.

10. The organic light-emitting display substrate according to claim 6, further comprising:
an organic light-emitting layer, wherein the organic light-emitting layer is disposed in the openings and electrically connected with the first electrode layer; and
a second electrode layer, wherein the organic light-emitting layer is disposed between the second electrode layer and the first electrode layer, and the second electrode layer is electrically connected with the organic light-emitting layer.

11. The organic light-emitting display substrate according to claim 1, wherein a material of the plurality of microlens arrays is photoresist.

12. A display panel, comprising an organic light-emitting display substrate, wherein the organic light-emitting display substrate is provided with a first display region and a second display region, the first display region being a photographing region, and the second display region being a conventional display region; and
the organic light-emitting display substrate comprises: a base and a pixel defining layer that are laminated, and a plurality of microlens arrays that are distributed at intervals on the pixel defining layer, wherein the plurality of microlens arrays are disposed in the first display region, the pixel defining layer is provided with a plurality of openings penetrating the pixel defining layer, and orthographic projections of the plurality of microlens arrays on the base and orthographic projections of the openings on the base do not overlap.

13. The display panel according to claim 12, wherein each of the plurality of microlens arrays comprises a plate and a plurality of spherical caps that are arranged in an array on the plate, the plate being disposed between bottom surfaces of the spherical caps and the pixel defining layer.

14. The display panel according to claim 13, wherein a thickness of each of the microlens arrays ranges 1 μm to 2 μm.

15. A display device, comprising the display panel as defined in claim 12.

16. A method for manufacturing an organic light-emitting display substrate, wherein the organic light-emitting display substrate is provided with a first display region and a second display region, the first display region being a photographing region, and the second display region being a conventional display region, the method comprising:
providing a base; and
sequentially forming, on the base, a pixel defining layer and a plurality of microlens arrays that are arranged at intervals, wherein the plurality of microlens arrays are disposed in the first display region, the pixel defining layer is provided with a plurality of openings penetrating the pixel defining layer, and orthographic projections of the plurality of microlens arrays on the base and orthographic projections of the openings on the base do not overlap.

17. The method for manufacturing the organic light-emitting display substrate according to claim 16, further comprising:
forming a first electrode layer on a side of the base, wherein the first electrode layer comprises a plurality of first electrodes; and
sequentially forming, on the base, the pixel defining layer and the plurality of microlens arrays that are arranged at intervals comprises:
forming the pixel defining layer on a side, away from the base, of the first electrode layer, and patterning the pixel defining layer to form the plurality of openings penetrating the pixel defining layer, wherein the orthographic projections of the openings on the base are within orthographic projections of the first electrodes on the base; and
forming a light transmitting material layer on a side, away from the base, of the pixel defining layer, and patterning the transparent material layer to form the plurality of microlens arrays, wherein the plurality of microlens arrays are disposed in the first display region, and the orthographic projections of the plurality of microlens arrays on the base and the orthographic projections of the openings on the base do not overlap.

18. The method for manufacturing the organic light-emitting display substrate according to claim 17, further comprising:
patterning the transparent material layer to form a plurality of spacers, wherein the plurality of spacers are disposed in the second display region, and orthographic projections of the plurality of spacers on the base and the orthographic projections of the openings on the base do not overlap.

19. The method for manufacturing the organic light-emitting display substrate according to claim 18, wherein forming the plurality of spacers at the same time of patterning the light transmitting material layer to form the plurality of microlens arrays comprises:
exposing the light transmitting material layer by using a halftone mask, wherein the halftone mask comprises a first exposure region corresponding to the plurality of microlens arrays and a second exposure region corresponding to the plurality of spacers, the first exposure region being a halftone region, and the second exposure region being a fully light transmitting region.

20. The method for manufacturing the organic light-emitting display substrate according to claim 19, wherein forming the plurality of spacers at the same time of patterning the light transmitting material layer to form the plurality of microlens arrays further comprises:
developing the exposed light transmitting material layer, to obtain a plurality of microlens arrays to be cured and a plurality of spacers to be cured; and
performing curing on the developed light transmitting material layer to form the plurality of microlens arrays and the plurality of spacers, comprising: performing primary curing, at a first temperature, on the developed light transmitting material layer, and performing secondary curing, at a second temperature, on the light transmitting material layer after the primary curing, wherein the first temperature is different from the second temperature.
